(19) United States
(12) Patent Application Publication
(10) Pub. No.: US 2026/0123344 A1
(43) Pub. Date: Apr. 30, 2026

(54) Semiconductor Substrate Bonder for Enhanced Precision with Zonal Electrostatic Chuck

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/928,205

(22) Filed: Oct. 28, 2024

(51) Int. Cl. H01L 21/683; H01L 23/00

(52) U.S. Cl. CPC H10P 72/722; H10W 72/071; H10W 80/163; H10W 80/312; H10W 80/327

(57) ABSTRACT

Disclosed herein is a semiconductor substrate bonder with a multi-zonal electrostatic chuck (ESC) that enables highly controllable pre-bonding from the substrate center progressively to the edge. Each ESC zone applies an independently controlled DC bias voltage for selective chucking and de-chucking, while pressurized gas or a retractable pin initiates center-based pre-bonding. This system is particularly suitable for hybrid bonding applications in semiconductor manufacturing.

### FIELD OF THE INVENTION

The present invention relates to semiconductor manufacturing and, more specifically, to systems for achieving high-precision hybrid bonding of semiconductor substrates.

### BACKGROUND OF THE INVENTION

Hybrid bonding is a technique in semiconductor manufacturing that involves pre-bonding dielectric layers, followed by bonding conductive interconnects, typically through an annealing process. This method enables the formation of high-density, multi-layer structures. During pre-bonding, substrates must be positioned face to face closely to form hydrogen bonds.

Conventional bonding systems, which rely on mechanical force applied by a bonder head at the substrate center, face challenges in meeting the precision required for hybrid bonding. A primary issue is the inconsistency of pre-bonding contact across the substrate. Additionally, conventional systems often initiate bonding with mechanical force from an actuator within the bonder head, which risks misalignment or damage to the substrate. These bonding heads are typically complex and costly.

As semiconductor devices increase in complexity and density, the demand for precise alignment has intensified, particularly for 3D systems that integrate multiple chiplets across large areas. Current bonding systems struggle to meet these alignment requirements, resulting in challenges in achieving consistent bonding for 3D systems.

The present invention addresses these challenges by improving the control over the pre-bonding process, enabling the application of controlled forces through the use of zonal electrostatic chuck technology, thereby eliminating the need for complex bonding heads.

### SUMMARY

In some embodiments, the invention discloses a semiconductor substrate bonder that incorporates a multi-zonal electrostatic chuck (ESC) to enhance the control and uniformity of the hybrid bonding process. The ESC includes multiple independently controlled zones, each equipped with an electrode and bias unit, allowing distinct DC bias voltages to be applied selectively to specific zones of the substrate. By selectively de-chucking zones in a concentric pattern, the bonding process can initiate at the center of the substrate and expand outward.

In certain implementations, each zone of the ESC is configured to apply a reverse polarity voltage during de-chucking to neutralize any residual surface charge, allowing smooth release of the substrate from the ESC. This controlled de-chucking avoids abrupt detachment, thereby maintaining substrate alignment and integrity and preventing warping or slippage during bonding.

In some embodiments, the ESC also incorporates surface grooves that channel high-pressure gas beneath the substrate. These grooves retain gas at a pressure higher than ambient, creating an upward force that moves the substrate toward the top substrate for pre-bonding when the DC bias voltage for a specific zone is deactivated.

In additional embodiments, a retractable pin positioned at the center of the ESC may be used to initiate bonding by gently pushing the substrate upward. This pin-based approach operates in conjunction with zonal de-chucking, enabling controlled initiation and expansion of bonding, thereby reducing the risk of misalignment. More specifically, retractable pins associated with other zones may be applied to expand progressively the pre-bonding to the edge of the substrate.

In some embodiments, a vertical position sensor is optionally used to measure the vertical coordinates of both the base and top substrates in a shared 3D coordinate system. These coordinates guide the movements of a movable stage holding the ESC and base substrate, and a positioning mechanism for the top substrate, to achieve optimized positioning for pre-bonding.

This zonal ESC-based bonder provides a reliable solution for controlled pre-bonding of semiconductor substrates. By facilitating independent DC bias control, pressurized gas application, and the use of a retractable pin, the invention improves bonding precision and uniformity, making it particularly suitable for advanced hybrid bonding applications in semiconductor manufacturing.

### BRIEF DESCRIPTIONS OF THE DRAWINGS

The accompanying drawings illustrate the following:

FIG. 1: A schematic representation of an exemplary bonder with a zonal ESC.

FIG. 2: An exemplary design of the zonal ESC.

FIG. 3A: A flowchart illustrating a pre-bonding process as part of hybrid bonding using the exemplary bonder.

FIG. 3B: A schematic diagram demonstrating the operating principle of the bonder utilizing the zonal ESC.

FIG. 4: An embodiment where pressurized gas stored within surface grooves of the zonal ESC is utilized to initiate pre-bonding at the substrate center.

FIG. 5: Another embodiment where a retractable pin is used to initiate pre-bonding at the substrate center.

### DETAILED DESCRIPTIONS

This section provides detailed embodiments of the present invention to ensure a comprehensive understanding. Specific examples are provided for clarity, but modifications and variations that align with the claims are considered within the scope of this invention. Conventional methods and components are discussed where relevant to underscore the distinct features of the invention.

### Definition

System Controller: The main controller that coordinates operations between the movable stage, moving mechanism, ESC, vertical position sensor, and alignment mechanisms.

Movable Stage: A mechanical platform capable of moving in at least two directions (X and Y axes) for positioning a base substrate with high precision. In some implementations, it can also move in the Z direction. In alignment processes, the movable stage controls the base substrate's position.

Stage Actuator: A component responsible for controlling the movement of the movable stage in various directions. It may include motors, piezoelectric elements, or other mechanisms to achieve fine motion control required for substrate positioning.

Moving Mechanism: A programmable mechanism capable of multi-directional movement and performing tasks such as picking, placing, or aligning objects, like a 6-axis robotic arm.

Electrostatic Chuck (ESC): A chuck that uses electrostatic forces to hold the substrate securely in place during processing.

Zonal Electrostatic Chuck (Zonal ESC): A type of ESC divided into multiple zones, each independently controlled by a DC bias voltage. This configuration enables selective chucking and de-chucking of individual zones, supporting controlled pre-bonding steps.

Bias Unit: A power supply that provides DC bias voltage to specific zones of the ESC. Each bias unit controls a particular electrode within the ESC, enabling selective chucking or de-chucking of individual zones.

Electrode: A conductive element within the ESC zones that applies the DC bias voltage to a specific zone of the ESC. Electrodes may vary in shape, size, and configuration depending on the zonal requirements for chucking and de-chucking.

Alignment Mark: A predefined pattern or structure placed on a substrate, such as a wafer or die, used as a reference for determining the position or orientation of the wafer or die in a bonding process.

Vertical Position Sensor: A sensor that determines the vertical position (Z-axis) of the substrate, ensuring that the substrates are positioned with high precision in the same 3D coordinate system. This sensor is critical for achieving accurate face-to-face positioning.

Hybrid Bonding: A semiconductor bonding technique involving the initial bonding of dielectric layers followed by the bonding of conductive interconnects, typically through an annealing process. This method allows for high-density, multi-layer structures.

Pre-Bonding: An initial attachment process in hybrid bonding where surfaces are brought close enough to allow weak molecular interactions, such as hydrogen bonds and van der Waals forces, to form between dielectric layers on the substrates.

Retractable Pin: A mechanism used to initiate pre-bonding by applying a controlled upward force to the center of the base substrate. The retractable pin can be selectively actuated to gently raise specific areas of the substrate toward the top substrate.

Pin Actuator: A device that controls the movement of the retractable pin, enabling it to engage or disengage the substrate as part of the bonding process. The pin actuator is managed by the pin controller.

Pressurized Gas System: A system that channels pressurized gas, such as argon, nitrogen, or helium through grooves in the ESC to apply an upward force to the substrate, aiding in the pre-bonding process by pushing the center or other specific areas of the substrate upward.

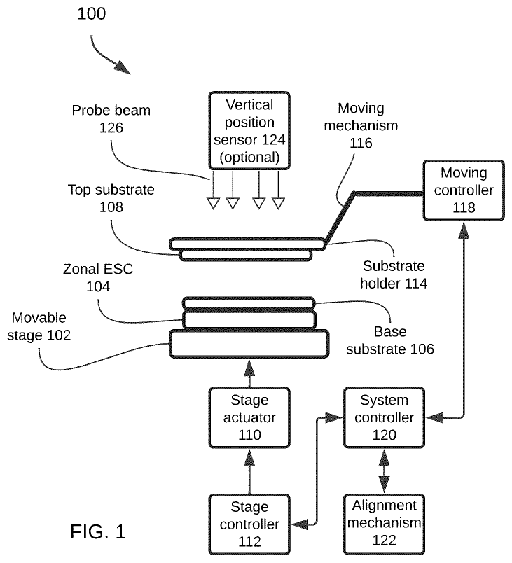

FIG. 1 illustrates a schematic representation of an exemplary substrate bonder, labeled as 100. The bonder 100 includes a base substrate 106 positioned on a zonal electrostatic chuck (ESC) 104, mounted on a movable stage 102.

In one embodiment, the ESC 104 has grooves etched onto its surface. The design incorporates surface grooves to introduce a controlled gas flow beneath the substrate at a pressure higher than the top surface pressure. This pressurized gas in the grooves creates an upward force on the substrate. When balanced with the downward electrostatic force created from the chucking's DC bias voltages, the substrate is held securely without full contact with the ESC surface. The gases may include, but are not limited to, nitrogen, argon, and helium.

In one implementation, groove patterns are designed concentrically, aligning with the zones of the ESC 104. Carefully controlled groove dimensions ensure that gas pressure balances the chucking force optimally, stabilizing the substrate.

In another embodiment, the bonder 100 includes retractable pins, commonly used in semiconductor processing systems for substrate handling. These pins enable smooth placement and retrieval of substrates on the ESC surface. Integrated within the ESC structure, the pins move vertically through small, precisely positioned openings in the chuck's surface. During substrate loading, the pins extend above the ESC surface, creating a platform to safely position the substrate before it contacts the ESC. Once the substrate is aligned, the pins retract, gently lowering it onto the chuck, where it remains until the chucking bias is applied.

This retractable pin system also facilitates substrate retrieval. When lifting is required, the pins extend from the ESC, raising the substrate to a predetermined height accessible to a robotic arm. This lifting process ensures that the wafer is not disturbed by direct mechanical force from the robotic arm, reducing risks of misalignment or surface damage.

In the present invention, the retractable pins can further be leveraged to push the center part of the base substrate 106 surface toward the top substrate 108, initiating pre-bonding at the substrate center while the ESC 104 still secures the base substrate 108. Furthermore, retractable pins associated with other zones may be applied to expand progressively the pre-bonding to the edge of the substrate.

The ESC 104 is mounted on a movable stage 102, providing structural support and precise positioning control. The bonder 100 also includes a stage controller 112, which controls stage movement via a stage actuator 110. The stage 102 allows high-precision movement, with nanometer-level accuracy, and can function as an XY-stage or an XYZ-stage.

For ultra-smooth, frictionless motion, high-precision mechanisms such as air bearings are crucial. Air bearings utilize a thin film of compressed air to support the moving stage, eliminating mechanical contact and reducing friction and wear typical of traditional bearings. This setup achieves stable, repeatable, precise movements with potential nanometer accuracy, enhancing longevity and enabling high-speed operation. Other mechanisms, such as magnetic or flexure bearings, may be used for low-friction movement, prioritizing repeatability and stability, making them ideal for high-precision bonders. These mechanisms are especially effective where positional accuracy over extended periods and variable loads is essential.

The stage actuator 110 manages multiple operating parameters. For a high-precision stage 102, critical parameters include ultra-precise position control along the X and Y axes, with movements measured in nanometers. Velocity and acceleration are optimized to ensure smooth, stable positioning with minimal overshoot and vibration. Step size or resolution is fine-tuned for small adjustments, and high-resolution encoder feedback allows real-time movement adjustments. The actuator's force or torque is regulated for delicate load handling, while travel limits prevent stage overreach, and load compensation ensures consistent performance. Smooth transitions are achieved via advanced jerk control, and homing procedures return the stage to reference positions with nanometer accuracy. In some implementations, the stage may also move vertically as an XYZ-stage.

The bonder 100 further includes a substrate holder 114 for holding the top substrate 108. The substrate holder 114 connects to a moving mechanism 116, which can be, for example, a 6-axis robotic arm. The 6-axis robotic arm allows precise 3D control, moving along and rotating around the X, Y, and Z axes (roll, pitch, and yaw), making it ideal for tasks requiring complex positioning. In one implementation, the substrate holder 114 may serve as the robotic arm's end effector, and its movement is controlled by a moving controller 118. In another implementation, the substrate holder 114 may be an ESC which can be used to mitigate effects of the substrate warpage.

The bonder's operations are managed by a system controller 120, which coordinates with the stage controller 112 and the moving controller 118. An alignment mechanism 122, managed by the system controller 120, aligns the base substrate 106 with the top substrate 108.

In one implementation, alignment is achieved using a camera positioned between the substrates to capture images of alignment marks on each substrate. The camera transmits these images to the system controller 120 that analyzes mark positions and calculates adjustments for alignment. The stage actuator 110 and/or the moving mechanism 116 then make fine positional corrections to one or both wafers based on this data. Alternatively, the alignment mechanism 122 may be placed on the bonder's upper part. Once aligned, the substrates are positioned for bonding, ensuring precise layer registration.

It is important that vertical positions of the substrates are measured with high precision, down to nanometer accuracy to position the substrates face to face. An optional vertical position sensor denoted as 124 is shown in FIG. 1. The sensor 124 emits a probe beam 126 to determine the vertical coordinate of the base substrate 106 in 3D space before top substrate 108 is loaded. Subsequently, the vertical coordinate of the top substrate 108 is measured before it is flipped. The measured coordinates are received by the system controller 120 which determined trajectories of the movements for both the base and the top substrates to reach precisely their pre-bonding positions. The sensor 124 can be implemented using various technologies. Laser-based sensors, such as time-of-flight (ToF) sensors, and ultrasonic sensors are commonly used for precision distance measurement. Laser-based sensors calculate the distance by measuring the time it takes for a laser beam to travel to an object and reflect back, providing high accuracy.

Ultrasonic sensors, on the other hand, use high-frequency sound waves to measure distance. By calculating the time required for the sound waves to bounce back from an object, ultrasonic sensors offer another method to measure distance with precision.

In another implementations, the sensor 124 may emit probe beams to probe the substrate's vertical coordinates at different locations of the substrate to ensure the substrates are strictly parallel to the XY plane.

In still another implementation, the thickness of the top substrate 108 can be determined by measuring the vertical coordinate before and after it is flipped, considering effects of the substrate holder 114.

After alignment, the base substrate 106 and top substrate 108 are positioned by the movable stage 102 and the moving mechanism 116, respectively, ready for pre-bonding in a hybrid bonding process.

In hybrid bonding, effective pre-bonding between dielectric layers requires bringing surfaces into nanometer range. Plasma activation introduces hydroxyl (OH) groups on each surface, facilitating hydrogen bonding when the surfaces approach within a range that allows hydrogen bonds to form between OH groups, creating an initial “pre-bond.”

In addition to hydrogen bonding, van der Waals forces-short-distance molecular attractions-contribute to adhesion at the interface, further stabilizing the initial bond. Together, these forces create a precise, uniform attachment without mechanical or external electrical forces. The wafers are then thermally treated, driving dehydration reactions at the interface to convert the hydrogen bonds into covalent Si—O—Si bonds, ensuring a durable final bond essential for hybrid bonding applications.

Initiating pre-bonding from the substrate center and progressing outward promotes uniform adhesion, avoiding air or particle entrapment that could lead to voids or weak points. This method allows controlled hydrogen bonding and van der Waals interaction across the surface, reducing stress and ensuring a defect-free bond, which is critical for high-quality thermal processing.

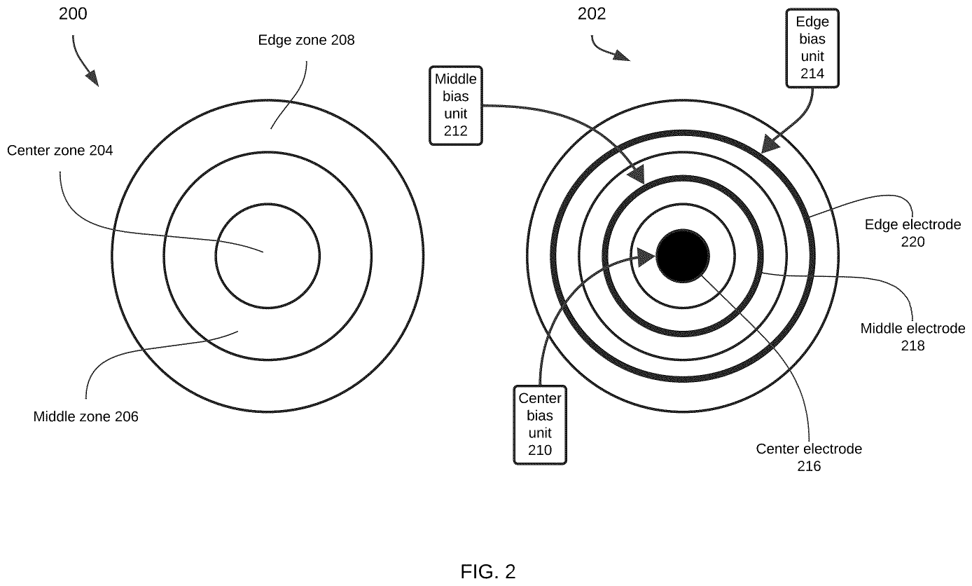

FIG. 2 depicts an exemplary design of the zonal ESC 104. The ESC 104 is divided into multiple zones, each with an independently controlled DC bias voltage. As shown in 200, the exemplary ESC 104 includes three independently controlled zones: center zone 204, middle zone 206, and edge zone 208. Each zone includes an independent electrode connected to a corresponding bias unit. Specifically, the center bias unit 210 provides a first DC bias voltage to the center zone 204 via a center electrode 216, the middle bias unit 212 provides a second voltage to the middle zone 206 via a middle electrode 218, and the edge bias unit 214 provides a third voltage to the edge zone 208 via an edge electrode 220. Each bias unit can deliver a unique voltage and can be independently switched on or off, allowing each zone of the ESC 104 to be independently chucked or de-chucked.

The design shown in FIG. 2 is for illustration only. The ESC may have more or fewer zones in a concentric configuration. Additionally, electrodes may vary in size or shape, and each electrode may consist of multiple connected segments.

In the embodiment shown in FIG. 1, the bonder 100 brings the base substrate 106 and top substrate 108 into close proximity. Upon reaching their positions, the ESC's center part is de-chucked by switching off the bias unit 212. In some implementations, a reverse polarity bias voltage may be applied to the electrode 216 to neutralize the surface charges, making de-chucking more effective.

Once the center of the base substrate 106 is released from the ESC 104, it is pushed upward to initiate center pre-bonding. This push can be achieved by the pressurized gas or by the retractable pin, applying mechanical force in a controlled fashion to push the base substrate at the center upward, initiating the pre-bonding process.

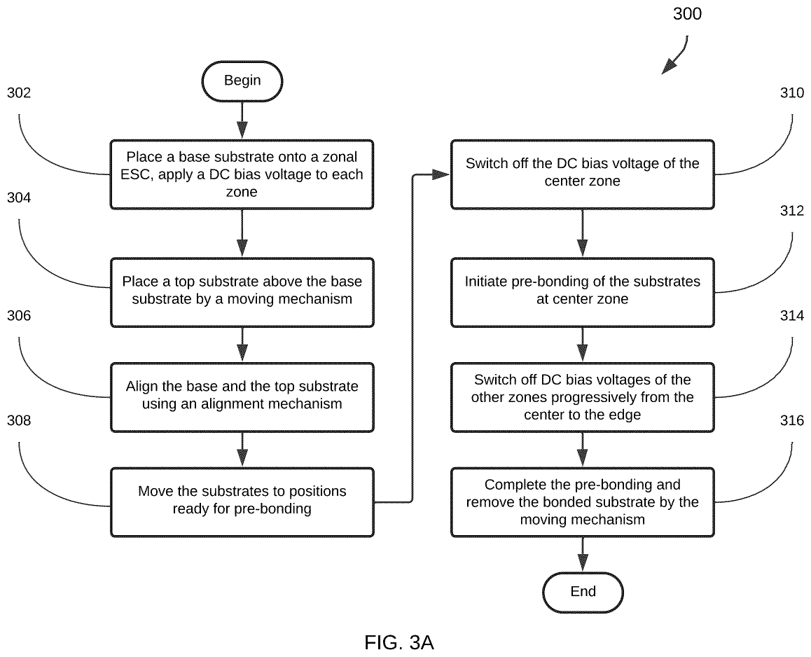

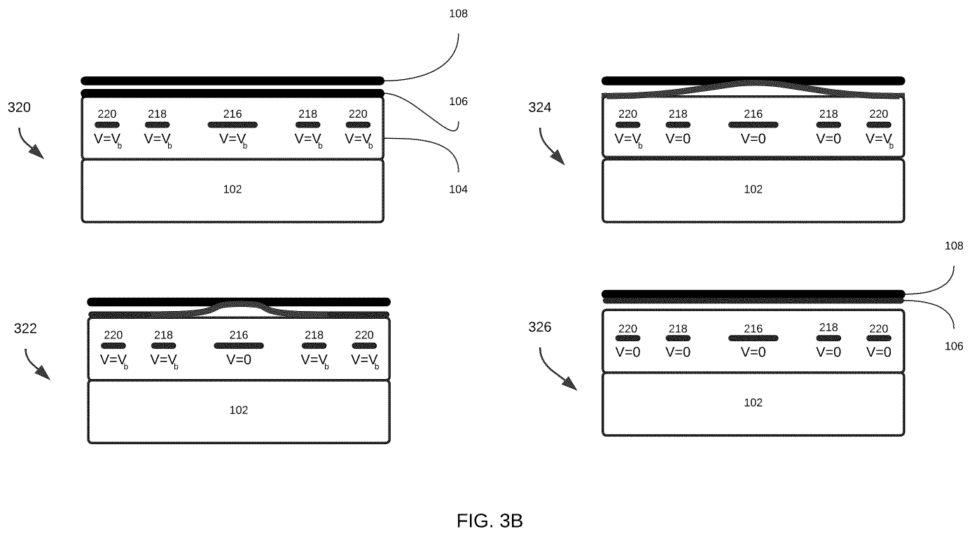

FIG. 3A presents a flowchart of a pre-bonding process 300 as part of a hybrid bonding process using the exemplary bonder 100. Process 300 begins at step 302, where a base substrate 106 is placed onto the ESC 104. As illustrated in 320 of FIG. 3B, the center electrode 216, middle electrode 218, and edge electrode 220 receive a DC bias voltage V_{b}, securing all three zones of the base substrate 106 to the ESC 104 via electrostatic forces. In some implementations, the vertical coordinate of the base substrate 106 may be measured by the vertical position sensor 124 and sent to the system controller 120.

In step 304, the top substrate 108 is positioned above the base substrate 106 by the moving mechanism 116. In some implementations, the vertical coordinate of the top substrate 108 may be measured by the sensor 124. The measured coordinate is sent to the system controller 120. Step 306 involves applying the alignment mechanism 122 to align the base and top substrates. In one implementation, the alignment mechanism 122 is located in the upper portion of the bonder 100. In another implementation, the alignment mechanism, such as a camera, is placed between the base and top substrates to capture alignment marks on each substrate. Upon obtaining alignment data, the movable stage 102 and moving mechanism 116 adjust the substrates to the positions, preparing them for pre-bonding in step 308, as shown in 320 of FIG. 3B. The measured vertical positions can be additionally used to bring the substrates precisely into the pre-bonding positions.

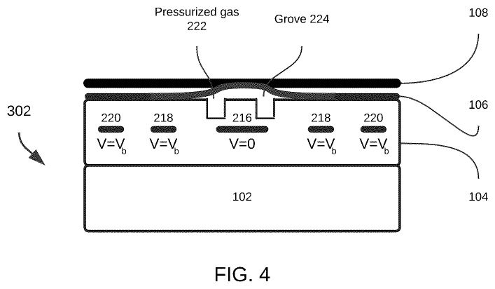

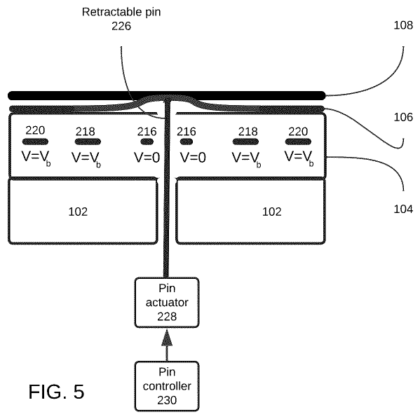

In step 310, the DC bias voltage to the center zone 204 is switched off. The center electrode 216 receives either zero voltage or a reverse polarity bias voltage to neutralize the surface of the center zone 204 on the ESC 104. The results are shown in 322 of FIG. 3B. At this point, the center of the base substrate 106 is pushed towards the top substrate 108. In one embodiment, as shown in FIG. 4, the pressurized gas 222, such as argon, stored in a groove 224, is released to apply pressure, moving the center of the base substrate 106. In another implementation, as shown in FIG. 5, a retractable pin 226 is used to push the center of the base substrate 106 upwards. The pin 226 is actuated by a pin actuator 228, which is controlled by a pin controller 230.

In step 312, the pre-bonding of the substrates is initiated through the formation of hydrogen bonds and van der Waals forces-weak molecular attractions acting at very short distances. Subsequently, in step 314, additional zones, such as middle zone 206 and edge zone 208, are de-chucked in a controlled sequence, completing the pre-bonding process at step 316, as illustrated in 324 and 326 in FIG. 3B.

Upon completing the pre-bonding, the bonded substrates, now a single unit, are removed by the moving mechanism 116 for subsequent processing, such as thermal treatment, to complete the hybrid bonding process.

1. A semiconductor bonder, comprising:
an electrostatic chuck (ESC) comprising a plurality of zones, each zone independently coupled to a DC bias voltage to generate electrostatic force for holding a base substrate;
a movable stage configured to support the ESC and the base substrate, wherein the movable stage is capable of moving the base substrate in at least an XY plane;
a moving mechanism connected to a substrate holder for holding a top substrate; and
a system controller configured to
align the base and top substrates via an alignment mechanism,
move the substrates, via the movable stage and the moving mechanism, to positions ready for pre-bonding,
switch off the DC bias voltages progressively from the center to the edge of the ESC to initiate and complete the pre-bonding.

2. The bonder of claim 1, wherein the ESC further comprises grooves on the surface for containing pressurized gas.

3. The bonder of claim 2, wherein the pressurized gas pushes a center zone of the base substrate upwards to initiate the pre-bonding after switching off the DC bias voltage for the zone.

4. The bonder of claim 3, wherein pressurized gas progressively pushes other zones of the ESC upwards from the center to the edge in response to switching off the DC bias voltages from the center to the edge zones.

5. The bonder of claim 2, wherein the pressurized gas is selected from a group consisting of argon, nitrogen and helium.

6. The bonder of claim 1, wherein the ESC and the movable stage, each comprising a plurality of opening hosting a plurality of retractable pins.

7. The bonder of claim 6, wherein a retractable pin located at the center zone is used to push the base substrate upwards to initiate the pre-bonding from the center zone.

8. The bonder of claim 7, wherein the retractable pins are moved upwards progressively from the center to the edge of the ESC to complete the pre-prebonding in response to switching off the DC bias voltage from center to edge zones.

9. The bonder of the claim 1, further comprising a vertical position sensor configured to measure vertical coordinates of the base and the top substrates in a 3D space.

10. The bonder of the claim 9, wherein the measured coordinates are used by the system controller to precisely position the base and the top substrates ready for the pre-bonding.

11. The bonder of the claim 1, wherein the zones are arranged concentrically.

12. A method for substrate bonding, comprising:
placing a base substrate onto an ESC with a plurality of zones, each zone coupled to an independently controlled DC bias voltage for generating electrostatic force for holding the base substrate;
placing a top substrate above the base substrate using a moving mechanism connected to a substrate holder;
aligning the base and the top substrates using an alignment mechanism;
moving the substrates to positions ready for pre-bonding;
switching off the DC bias voltage for a center zone of the ESC;
initiating pre-bonding of the substrates at the center zone;
switching off the DC bias voltages of the other zones progressively from the center to the edge; and
completing the pre-bonding and removing the bonded substrates with the moving mechanism.

13. The method of claim 12, further comprising pushing the center zone of the base substrate upwards with pressurized gas stored in grooves on the surface of the ESC to initiate the pre-bonding.

14. The method of claim 13, further comprising progressively pushing other parts of the base substrate upwards with the pressurized gas from the center to the edge zones.

15. The method of claim 12, further comprising pushing the center zone of the base substrate upwards with a retractable pin through an opening through the ESC and the movable stage.

16. An ESC of a bonder for holding a base substrate, comprising:
a plurality of concentric zones, each zone comprising an electrode coupled to an independently controlled DC bias voltage, wherein the DC bias voltage generates electrostatic force to the hold the base substrate; and
a dielectric layer on top of the ESC comprising grooves that overlap with each of the zones, wherein the grooves contain pressurized gas utilized to progressively push the base substrate upwards from the center to the edge in response to switch off the DC bias voltages accordingly.

17. The ESC of claim 16, wherein the DC bias voltage for each zone is switched off, followed by applying a reverse polarity bias voltage to neutralize surface charge of the zone.

18. The ESC of claim 16, the pressurized gas is selected from a group consisting of argon, nitrogen and helium.

19. The ESC of claim 16, wherein the ESC is installed on a movable stage.

20. The ESC of claim 19, wherein the movable stage is configured to move at least in XY plane.
